(19) United States
(12) Patent Application Publication
(10) Pub. No.: US 2012/0001544 A1
(43) Pub. Date: Jan. 5, 2012

(54) LIGHT EMITTING MODULE AND METHOD OF MANUFACTURING THE SAME

(75) Inventors: Tae Hoon KIM, Gyeonggi-do (KR); Sang Hyun SHIN, Gyeonggi-do (KR); Cheol Ho HEO, Busan (KR); Young Ki LEE, Gyeonggi-do (KR); Ji Hyun PARK, Seoul (KR); Ki Ho SEO, Gyeonggi-do (KR)

(73) Assignee: SAMSUNG ELECTRO-MECHANICS CO., LTD.

(21) Appl. No.: 12/904,512

(22) Filed: Oct. 14, 2010

(30) Foreign Application Priority Data
Jul. 1, 2010 (KR) 10-2010-0063318

(51) Int. Cl. H01J 7/44; H01J 9/00

(52) U.S. Cl. 315/32; 445/23

(57) ABSTRACT

Disclosed are a light emitting module and a method of manufacturing the light emitting module. The light emitting module includes: a heat radiating substrate which includes a metal substrate with through holes, an internal insulating layer formed along inner walls of the through holes, and an external insulating layer covering all outer surfaces of the metal substrate; a light emitting component unit disposed on a top surface of the heat radiating substrate; a driving circuit unit which is electrically connected to the light emitting component unit, and is mounted on the heat radiating substrate to apply a driving signal to the light emitting component unit; a passive component which is mounted on the heat radiating substrate and is electrically connected to the driving circuit unit; and circuit wiring layers which are disposed on a top and a bottom of the heat radiating substrate, respectively, and are interconnected therebetween through vias formed on the through holes with the internal insulating layer of the heat radiating substrate, and play a role of electrical interconnection of the driving circuit unit and the light emitting component unit, or the driving circuit unit and the passive component.

### CROSS-REFERENCE TO RELATED APPLICATIONS

This application claims the benefit of Korean Patent Application No. 10-2010-0063318 filed with the Korea Intellectual Property Office on Jul. 1, 2010, the disclosure of which is incorporated herein by reference.

### BACKGROUND OF THE INVENTION

1. Field of the Invention

The present invention relates to a light emitting module and a method of manufacturing the same; and, more particularly, to a light emitting module including a heat radiating substrate and a method of manufacturing the same.

2. Description of the Related Art

A light emitting module refers to a device for generating light, and has been used as backlights of lighting systems, key pads, and displays, and light sources of vehicle head lamps. Additionally, the light emitting module may provide a variety of colors by either spontaneous generation of light, or a change in wavelengths of light through a color filter, and thus it may be used as a display.

As such, the light emitting module may include a light emitting component for generating light and a driving circuit unit for driving the light emitting component.

In case where a light emitting module is driven in the prior art, there has been produced heat in the light emitting component, or in the driving circuit unit. The produced heat results in deterioration of the light emitting component and the driving circuit unit, and thus the light emitting module may have an inferior efficiency or a shorter lifetime.

Also, due to a temperature difference between the light emitting component and the driving circuit unit, there has been a problem in that noises occur in the light emitting module.

### SUMMARY OF THE INVENTION

The present invention has been proposed in order to overcome the above-described problems and it is, therefore, an object of the present invention to provide a light emitting module, which includes a heat radiating substrate constituted by a light emitting component and a driving circuit unit, so that it is possible to effectively emit heat produced during operation of the light emitting module to the outside, which results in a reduction in deterioration of the light emitting module and the driving circuit unit due to the heat, as well as a decrease in a temperature difference between the light emitting component and the driving circuit unit.

In accordance with one aspect of the present invention to achieve the object, there is provided a light emitting module including: a heat radiating substrate which includes a metal substrate with through holes, an internal insulating layer formed along inner walls of the through holes, and an external insulating layer covering all outer surfaces of the metal substrate; a light emitting component unit disposed on a top surface of the heat radiating substrate; a driving circuit unit which is electrically connected to the light emitting component unit, and is mounted on the heat radiating substrate to apply a driving signal to the light emitting component unit; a passive component which is mounted on the heat radiating substrate and is electrically connected to the driving circuit unit; and circuit wiring layers which are disposed on a top and a bottom of the heat radiating substrate, respectively, and are interconnected therebetween through vias formed on the through holes with the internal insulating layer of the heat radiating substrate, and play a role of electrical interconnection of the driving circuit unit and the light emitting component unit, or the driving circuit unit and the passive component.

Also, the internal insulating layer and the external insulating layer may be integrally formed.

Also, the internal insulating layer and the external insulating layer may be made of any one of oxide, silicon oxide, silicon nitride, boron nitride, and aluminum nitride of metallic materials constituting the metal substrate.

Also, the light emitting component unit may include any one of an organic EL, an inorganic EL, and an LED.

Also, the light emitting component unit may further include a light emitting component substrate having the light emitting component mounted thereon.

Also, the light emitting component substrate may include an additional metal substrate, and an additional insulating layer which covers all outer surfaces of the additional metal substrate.

Also, the light emitting component substrate may have additional vias formed therethrough by which the light emitting component is electrically interconnected to the driving circuit unit mounted on the heat radiating substrate.

Also, the light emitting component substrate may have connection wirings by which the light emitting component is electrically interconnected to the driving circuit unit mounted on the radiating substrate, wherein the connection wirings are disposed on the side surface along the top surface of the light emitting component substrate.

Also, the light emitting component unit and the heat radiating substrate may be bonded on each other through an adhesion member.

Also, the adhesion member may include a heat conductive filler.

Also, the adhesion member may electrically connect the connection wirings to the circuit wiring layers, and includes a solder and a conductive adhesive resin.

In accordance with another aspect of the present invention to achieve the object, there is provided a method of manufacturing a light emitting module including the steps of: forming a heat radiating substrate which includes a metal substrate with through holes, an internal insulating layer formed along inner walls of the through holes, and an external insulating layer covering all outer surfaces of the metal substrate; forming circuit wiring layers on a top and a bottom of the heat radiating substrate to provide interlayer connection through vias formed on through holes with internal insulating layer; and mounting a light emitting component unit, a driving circuit unit, and a passive component on a top surface of the heat radiating substrate, wherein the driving circuit unit, the driving circuit unit, and the passive component are interconnected to one another through the circuit wiring layers.

Also, the internal insulating layer and the external insulting layer may be formed by performing anodizing treatment for surfaces of the metal substrate with the through holes, or by using vapor deposition of a heat conductive insulating material.

Also, the light emitting component unit may include any one of an organic EL, an inorganic EL and an LED.

Also, the light emitting component unit may include a light emitting component substrate having the light emitting component mounted thereon.

Also, the light emitting component substrate may include an additional metal substrate, and an additional insulating layer formed on all outer surfaces of the additional metal substrate, wherein the additional insulating layer is formed by anodizing treatment for surfaces of the additional metal substrate, or by using vapor deposition of a heat conductive insulating material.

Also, the light emitting component unit and the heat radiating substrate may be bonded through an adhesion member.

Also, the adhesion member may include a heat conductive filler.

Also, the light emitting component substrate and the heat radiating substrate may be electrically interconnected to each other, and the adhesion member is formed of a solder or a conductive adhesive resin.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a part of a light emitting module in accordance with a first embodiment of the present invention;

FIG. 2 is a cross-sectional view showing a part of a light emitting module in accordance with a second embodiment of the present invention;

FIG. 3 is a cross-sectional view showing a part of a light emitting module in accordance with a third embodiment of the present invention;

FIGS. 4 to 9 are cross-sectional views showing methods of manufacturing light emitting modules in accordance with a fourth embodiment of the present invention, respectively; and

FIGS. 9 to 11 are cross-sectional views showing methods of manufacturing light emitting modules in accordance with a fifth embodiment of the present invention, respectively.

### DETAILED DESCRIPTION OF THE PREFERABLE EMBODIMENTS

Embodiments of a light emitting device and a method for manufacturing the same in accordance with the present invention will be described in detail with reference to the accompanying drawings. When describing them with reference to the drawings, the same or corresponding component is represented by the same reference numeral and repeated description thereof will be omitted.

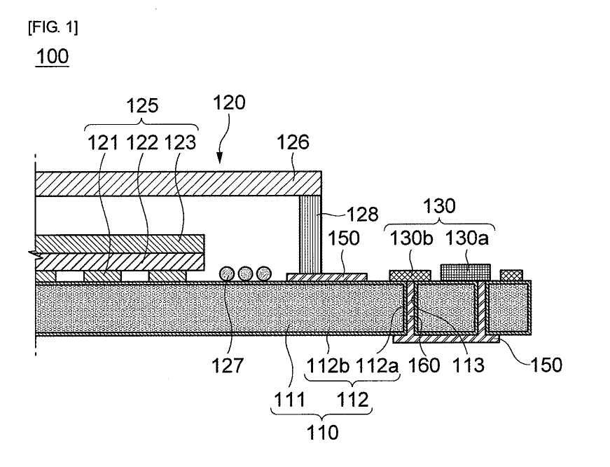

FIG. 1 is a cross-sectional view showing a part of a light emitting module in accordance with a first embodiment of the present invention.

Referring to FIG. 1, the light emitting module 100 in accordance with the first embodiment of the present invention may include a heat radiating substrate 110, a light emitting component unit 120, a driving circuit unit 130, a passive component 140, and circuit wiring layers 150.

Herein, the heat radiating substrate 110 may include a metal substrate 111 with through holes 113 formed through, and an insulating layer 112 for electrical insulation of the metal substrate 111. The metal substrate 111 may be made of a metallic material with a high heat conductivity, for example, Al, Ag, Cu, Fe, Cr, Mg, and an alloy of at least one of these metallic materials. Thus, the heat radiating substrate 110 may easily emit heat to the outside through heat transfer of the metal substrate 111.

Herein, the insulating layer 112 may include an internal insulating layer 112a disposed on inner walls of the through holes 113, and an external insulating layer 112b covering all outer surfaces of the metal substrate 111.

The circuit wiring layers 150 disposed on each of the top and bottom of the heat radiating substrate 110 are electrically connected to each other through vias 160 disposed within the through holes 113 including the internal insulating layer 112a. That is, the heat radiating substrate 110 has the circuit wiring layers 150 formed on both sides thereof, so that it is possible to enhance a degree of integration among the light emitting component unit 120, a driving circuit unit 130, and a passive component 140, all of which are to be mounted on the heat radiating substrate 110.

The internal insulating layer 112a and the external insulating layer 112b may be made of the same insulating material. In addition, the internal insulating layer 112a and the external insulating layer 112b may be integrally formed. The insulating layer 112 is formed with the internal insulating layer 112a and the external insulating layer 112b, each having a material of a superior heat transfer conductivity, so that the insulating layer 112 can prevent heat emission efficiency of the heat radiating substrate 110 from being reduced. Herein, as for materials of the insulating layer 112, any one of oxide, silicon oxide, silicon nitride, boron nitride, and aluminum nitride of the metal substrate may be used.

The light emitting component unit 120 may be disposed on the heat radiating substrate 110. Thus, heat produced during operation of the light emitting component unit 120 may be emitted to the outside through the heat radiating substrate 110, so that it is possible to prevent the light emitting component unit 120 from being deteriorated due to the heat. Therefore, it is possible to increase a lifetime and an efficiency of the light emitting module 100.

The light emitting component unit 120 may include a light emitting component 125 for generating light.

The light emitting component 125 may include first and second electrodes 121 and 123, and an organic light emitting layer 122. The organic light emitting layer 122 is interposed between the electrodes 121 and 123 and generates light through recombination of electrons and holes injected on each of the first and second electrodes 121 and 123. That is, the light emitting component 125 may be an organic EL.

Herein, the first electrode 121 may be a light-reflective electrode made of a conductive material capable of upward-reflecting light, for example, Ag or Cu. Also, the second electrode 123 may be a light-transmissive electrode made of a conductive material capable of transmitting light, for example, ITO.

Each of the first and second electrodes 121 and 123 may be formed in a stripe shape. In this case, the first and second electrodes 121 and 123 may intersect with each other to define a plurality of pixels. Also, although not shown in the drawings, each of the top and bottom of the organic light emitting layer 122 may further have an electron injection layer, an electron transfer layer, a hole transfer layer, and a hole injection layer, so as to easily transfer the electrons and the holes to the organic light emitting layer 122.

Although it is illustrated in the embodiment of the present invention that the light emitting component 125 may correspond to an organic EL of a passive matrix type, the present invention is not limited thereto. Alternatively, the light emitting component 125 may be an organic EL of an active matrix type. Also, although it is illustrated that the light emitting component 125 corresponds to an organic EL, the present invention is not limited thereto. For example, the light emitting component 125 may be an inorganic EL or LED.

In addition, the light emitting component unit 120 may further include a sealing substrate 126 disposed on the heat radiating substrate 110 including the light emitting component 125. In this case, a sealing member 128 is interposed between the heat radiating substrate 110 and the sealing substrate 126, thereby bonding the heat radiating substrate 110 to the sealing substrate 126 so as to seal the light emitting component 125 from the outside. Herein, the sealing substrate 126 may be made of light-transmissive glass, or optical transmissive plastic. Also, the sealing member 128 may be made of UV curable adhesive resin, but the material of the sealing member 128 is not limited by the present invention.

Also, in order to remove moisture within the light emitting component 125, or moisture permeating from the outside, a getter 127 may be further disposed within the sealing area. This is because the light emitting component 125, in particular, organic EL, is sensitive to moisture, and thus has a reduced lifetime.

The driving circuit unit 130 may be disposed on the heat radiating substrate 110. Thus, effective heat emission from the driving circuit unit 130 may be implemented, so that it is possible to prevent the driving circuit unit 130 from being deteriorated due to the produced heat.

The driving circuit unit 130 is electrically connected to the light emitting component unit 120 through the circuit wiring layers 150 formed on the heat radiating substrate 110, and applies a driving signal used for driving of the light emitting component unit 120 to the light emitting component unit 120. In this case, both the driving circuit unit 130 and the light emitting component unit 120 may be mounted on the heat radiating substrate 110, so it is possible to prevent occurrence of noises due to a temperature difference between the driving circuit unit 130 and the light emitting component unit 120.

The passive component 140 may be formed on the heat radiating substrate 110. The passive component 140 may be electrically connected to the driving circuit unit 130 or the light emitting component unit 120 by the circuit wiring layers 150 formed on the heat radiating substrate 110. Herein, the passive component 140 may include a capacitor, a resistor, an inductor, and so on.

The passive component 140 and the driving circuit unit 130 may be electrically connected to each other through the circuit wiring layers 150 which are disposed on the top and bottom of the heat radiating substrate 110, respectively. In this case, the circuit wirings used between the light emitting component unit 120 and the driving circuit unit 130, between the light emitting component unit 120 and the passive component 140, and between the passive component 140 and the driving circuit unit 130 should be insulated from one another so as to provide electrical interconnection, which causes a limit to formation of closely-spaced circuit wirings on the same area.

Also, each of components, that is, light emitting component unit 120, the driving circuit unit 130, and the passive component 140, should be mounted on the heat radiating substrate 110 while keeping away from the circuit wirings, so there may be a limitation to reduction of the area of the heat radiating substrate 110, in particular, the size of the light emitting module. However, as in the embodiment of the present invention, the circuit wiring layers 150 are formed on the top and bottom of the heat radiating substrate 110, so that it is possible to increase density of the circuit wirings, as well as a degree of integration between respective components.

Therefore, as in the embodiment of the present invention, the light emitting module is constructed with the light emitting component unit and the driving circuit unit, so that it is possible to effectively emit heat produced from the light emitting module itself, which results in prevention problems due to the deterioration caused by the produced heat, such as a lowered efficiency and a shorter lifetime of the light emitting module.

Also, in the light emitting module of the present invention, the light emitting component unit and the driving circuit unit are mounted on one heat radiating substrate, so that it is possible to reduce noises caused by a temperature difference between the light emitting component unit and the driving circuit unit.

Also, the light emitting module of the present invention is constructed with a heat radiating substrate, both surfaces of which have circuit wiring layers formed thereon, so that it is possible to increase degrees of integration of circuit wirings and parts mounted on the heat radiating substrate.

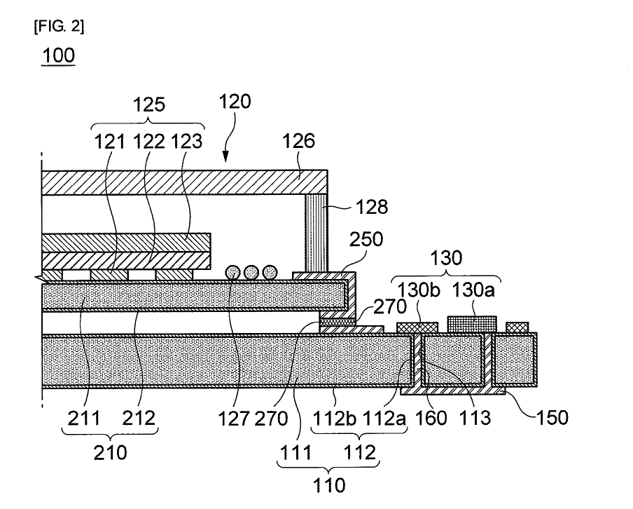

FIG. 2 is a cross-sectional view showing a part of a light emitting module in accordance with a second embodiment of the present invention. Herein, the light emitting module of the second embodiment of the present invention has the same technical construction as that of the first embodiment of the present invention, except for a construction of the light emitting component unit. Thus, the repeated description thereof will be omitted, and like reference numerals are given the same technical constructions.

Referring to FIG. 2, the light emitting module 100 in accordance with a second embodiment of the present invention may include a heat radiating substrate 110, a light emitting component unit 120, a driving circuit unit 130, a passive component 140, and circuit wiring layers 150. Herein, the light emitting component unit 120, the driving circuit unit 130, and the passive component 140 may be electrically connected to one another through the circuit wiring layers 150 each disposed on the top and the bottom surfaces of the heat radiating substrate 110.

The light emitting component unit 120 may include a light emitting component 125, and a light emitting component substrate 210 on which the light emitting component 125 is mounted. Also, the light emitting component unit 120 may further include the sealing substrate 126 which is bonded on the light emitting component substrate 210 so as to seal the light emitting component 125 from the outside. In this case, the bonding of the light emitting component substrate 210 and the sealing substrate 126 may be made through the sealing member 128 interposed therebetween.

The light emitting component substrate 210 may have constructions identical to those of the heat radiating substrate 110. That is, the light emitting component substrate 210 may include an additional metal substrate 211 and an additional insulating layer 212 covering all outer surfaces of the additional metal substrate 211.

Herein, the additional metal substrate 211 may be made of a material with a superior heat conductivity, for example, Al, Ag, Cu, Fe, Cr, Mg, and one or an alloy of one or more of these metallic materials.

Also, as for the material of the additional insulating layer 212, one of oxide, silicon oxide, silicon nitride, boron nitride, and aluminum nitride of the additional metal substrate 211 may be used. Thus, the heat produced from the light emitting component 125 may be emitted to the outside through the light emitting component substrate 210, as well as through the heat radiating substrate 110.

The light emitting component substrate 210 may have a connection wiring 250 for electrically interconnection of the light emitting component 125 and the driving circuit unit 130. Herein, the connection wiring 250 connected to the light emitting component 125 may be disposed along the side surface of the light emitting component substrate 210, and is in contact with the circuit wiring layer 150 of the heat radiating substrate 110 to thereby electrically interconnect the light emitting component unit 120 to the driving circuit unit 130.

The connection wiring 250 and the circuit wiring layer 150 may be electrically connected to each other through a conductive adhesion member 270. As for the conductive adhesion member 270, a solder or a conductive adhesive resin may be used. The conductive adhesion member is used for electrical connection between the connection wiring 250 and the circuit wiring layer 150. In addition, the conductive adhesion member 270 may play a role of adhesion member for bonding the light emitting component substrate 210 and the heat radiating substrate 110, that is, the light emitting component unit 120 and the heat radiating substrate 110. As such, the conductive adhesion member 270 makes effective transfer of heat from the light emitting component substrate 210 to the light emitting module 100, so that it is possible to provide even higher heat radiation effect.

In addition to this, although not shown in the drawings, an adhesion member is further provided between the light emitting component substrate 210 and the heat radiating substrate 110, so that it is possible to stably fix the light emitting component unit 120 on the heat radiating substrate 110. Herein, the adhesion member may further include a heat conductive filler by which heat can be effectively transferred from the light emitting component substrate 210 to the heat radiating substrate 110. In this case, as for the heat conductive filler, one of metal oxide, metal nitride, silicon oxide, silicon nitride, and so on may be exemplified.

Therefore, as in the embodiment of the present invention, a light emitting component unit further includes a light emitting component substrate with heat radiation effect, so that it is possible to increase the heat radiation effect of the light emitting module.

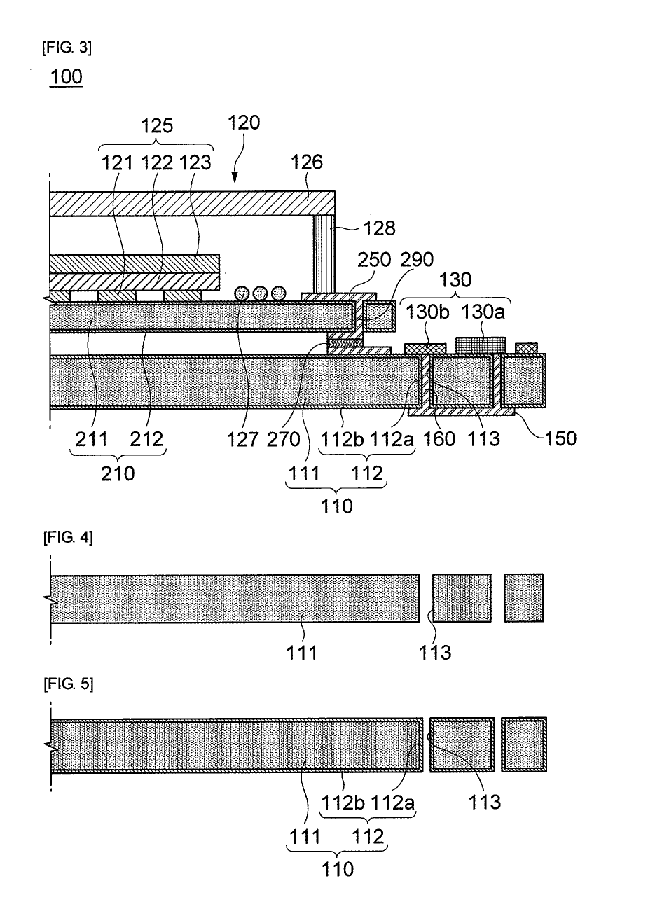

FIG. 3 is a cross-sectional view showing a part of a light emitting module in accordance with a third embodiment of the present invention. Herein, the light emitting module of the third embodiment of the present invention has the same technical construction as that of the first embodiment of the present invention, except for a construction of the light emitting component substrate. Thus, the repeated description thereof will be omitted, and like reference numerals are given the same technical constructions.

Referring to FIG. 3, the light emitting module 100 of the third embodiment of the present invention may include a heat radiating substrate 110, a light emitting component unit 120, a driving circuit unit 130, a passive component 140, and circuit wiring layers 150. Herein, by the circuit wiring layers 150 each disposed on the top and bottom surfaces of the heat radiating substrate 110, the light emitting component unit 120, the driving circuit unit 130, and the passive component 140 may be electrically interconnected to one another.

The light emitting component unit 120 may include the light emitting component unit 120 formed on the light emitting component substrate 210. Herein, the light emitting component substrate 210 may include vias 260 through which interlayer-connection is made, and connection wirings 250 each disposed on the top and the bottom of the light emitting component substrate 210. In this case, the connection wirings 250 are in electrical contact with the circuit wiring layer 150 of the heat radiating substrate 110, and thus the light emitting component unit 120 and the driving circuit unit 130 are electrically interconnected to each other.

Therefore, as in the embodiment of the present invention, vias of the light emitting component substrate are used for electrical connection of the light emitting component unit and the driving circuit unit disposed on the heat radiating substrate.

Hereinafter, a description will be given of a process of manufacturing the light emitting module in accordance with an embodiment of the present invention with reference to FIGS. 4 to 11.

FIGS. 4 to 9 are cross-sectional views showing methods of manufacturing the light emitting module in accordance with a fourth embodiment of the present invention, respectively.

Referring to FIG. 4, the light emitting module may be manufactured by performing the following steps. First, the metal substrate 111 is provided. The metal substrate 111 may be made of a metallic material with a high heat conductivity, for example, Al, Ag, Cu, Fe, Cr, Mg, and an alloy of at least one of these metals.

Thereafter, the metal substrate 11 has through holes 113 formed therein to connect the top surface to the bottom surface thereof. Herein, the through holes 113 may be formed by an etching process employing a photo process. Also, in the process of forming the metal substrate 111, the through holes 113 may be also formed. For example, in case where the metal substrate 111 is formed through a plating process, only remaining regions except for the regions of the formed through holes are subjected to a plating process to thereby form the metal substrate 111 with the through holes 113.

Referring to FIG. 5, after the through holes 113 are formed on the metal substrate 111, an internal insulating layer 112a disposed on the inner walls of the through holes 113 and an external insulating layer 112b disposed on all outer surfaces of the metal substrate 111 may be formed. Thus, the heat radiating substrate 110 may be formed which includes the insulating layer 112 disposed on the outer surfaces of the metal substrate 111 having the through holes 113.

The internal insulating layer 112a and the external insulating layer 112b may be formed by performing anodizing treatment for the surfaces of the metal substrate 111. That is, the internal insulating layer 112a and the external insulating layer 112b may be made of metal oxide constituting the metal substrate 111.

Herein, as for another example of forming the internal insulating layer 112a and the external insulating layer 112b, vapor deposition of a heat conductive insulating material may be used. In this case, as for the heat-conductive insulating material, one of aluminum oxide, silicon oxide, silicon nitride, boron nitride, and aluminum nitride may be exemplified.

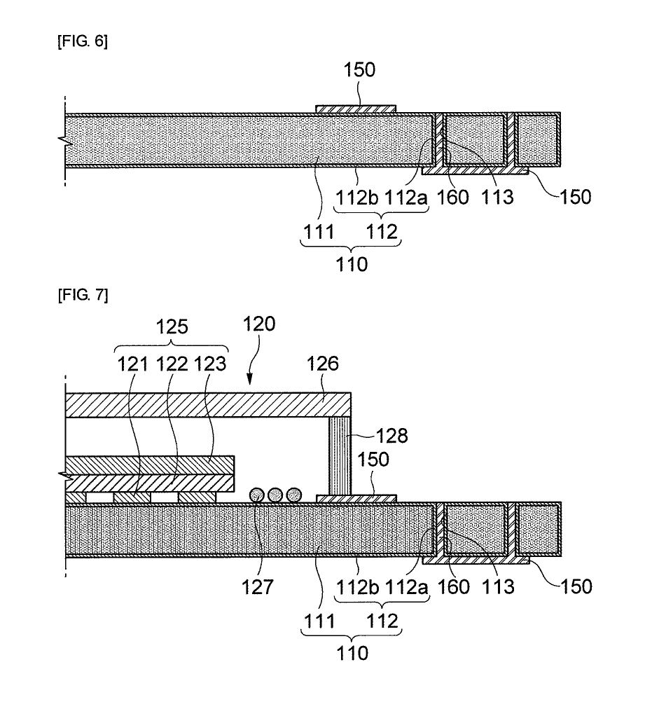

Referring to FIG. 6, after forming the heat radiating substrate 110, vias 160 and circuit wiring layers 150 may be formed. The vias 160 are disposed at the through holes 113 with the internal insulating layer 112a, and the circuit wiring layers 150 are disposed on the top and the bottom of the heat radiating substrate 110 and are interconnected therebetween through the vias 160.

Herein, in order to form the circuit wiring layers 150 and the vias 160, the heat radiating substrate 110 is subjected to an electro-less plating process to thereby form a seed layer. Thereafter, a resist pattern for exposing the vias 160 and the circuit wiring layers 150 to be formed on the seed layer is formed, and then an electro plating process using the seed layer is selectively performed, so that the vias 160 and the circuit wiring layers 150 are formed. Thereafter, after removal of the resist pattern, the seed layer disposed on the lower portion of the resist pattern is removed.

Although it is illustrated in the embodiment of the present invention that the circuit wiring layers 150 and the vias 160 are formed using the plating process, the present invention is not limited thereto, and the circuit wiring layers 150 and the vias 160 may be formed through an etching process and a deposition process of metal.

Referring to FIG. 7, after formation of the vias 160 and the circuit wiring layers 150, the light emitting component unit 120 is formed on the heat radiating substrate 110.

Herein, the light emitting component unit 120 may be formed by performing the following steps. First, the heat radiating substrate 110 has the light emitting component 125 formed thereon. The light emitting component 125 includes a first electrode 121, an organic light emitting layer 122, and a second electrode 123, which are placed in order. Herein, the first and second electrodes 121 and 123 may be electrically connected to the circuit wiring layers 150 formed on the heat radiating substrate 110, respectively.

In addition to this, although not shown in the drawings, an electron injection layer and an electron transfer layer may be formed between the first electrode 121 and the organic light emitting layer 122, and between the organic light emitting layer 122 and the second electrode 123, respectively, so as to easily transfer electrons and holes to the organic light emitting layer 122. For example, in case where the first electrode 121 is a cathode and the second electrode 123 is an anode, any one of an electron injection layer and an electron transfer layer may be formed between the first electrode 121 and the organic light emitting layer 122, and a hole transfer layer and a hole injection layer may be formed between the organic light emitting layer 122 and the second electrode 123.

Herein, although it is illustrated with the assumption in which the light emitting component 125 is an organic EL, the present invention is not limited thereto, and the light emitting component 125 may be an inorganic EL or an LED.

After the light emitting component 125 is formed on the heat radiating substrate 110, getters 127 are disposed to remove the inner moisture while being adjacent to the light emitting component 125.

Thereafter, the sealing member 128 is formed along the periphery of the light emitting component 125 and the getters 127, and then the sealing substrate 126 is bonded on the heat radiating substrate 110, including the light emitting component 125 and the getters 127, by using the sealing member 128. Therefore, the light emitting component unit 120 may be formed.

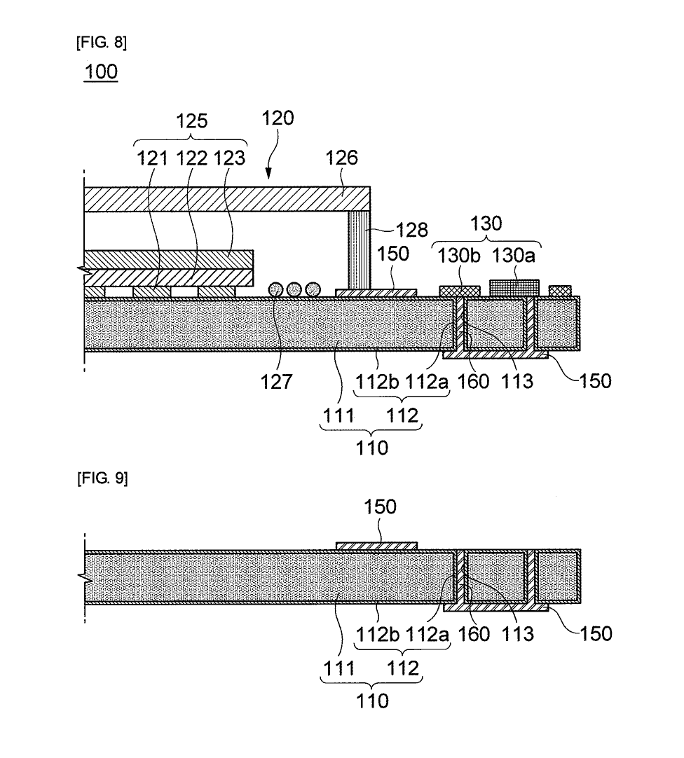

Referring to FIG. 8, after formation of the light emitting component unit 120, the driving circuit unit 130 and the passive component 140 are mounted on the heat radiating substrate 110. Herein, the driving circuit unit 130 may be electrically connected to the light emitting component unit 120 through the circuit wiring layers 150 formed on the heat radiating substrate 110 to thereby apply a driving signal to it. Also, the driving circuit unit 130 and the passive component 140 may be electrically interconnected to each other through the circuit wiring layers 150 formed on the heat radiating substrate 110. In this case, the driving circuit unit 130 and the passive component 140 may be electrically interconnected to each other by the circuit wiring layer 150 disposed on the lower portion of the heat radiating substrate 110 through the vias 160.

However, although it is illustrated in the embodiment of the present invention that the driving circuit unit 130 and the passive component 140 are electrically interconnected to each other through the circuit wiring layer 150 disposed on the lower portion of the heat radiating substrate 110, the present invention is not limited thereto, and the driving circuit unit 130 and the passive component 140 may be changed depending on a design structure. For example, the driving circuit unit 130 and the light emitting component unit 120 may be electrically interconnected to each other by the circuit wiring layer 150 disposed on the lower portion of the heat radiating substrate 110 through the via.

Therefore, as in the embodiment of the present invention, it is possible to form both a light emitting component unit and a driving circuit unit on one heat radiating substrate, thereby implementing an improved heat-radiation efficiency, which results in a longer lifetime and an improved efficiency of a light emitting module. In addition, it is possible to simplify corresponding processes, thereby reducing a process's cost.

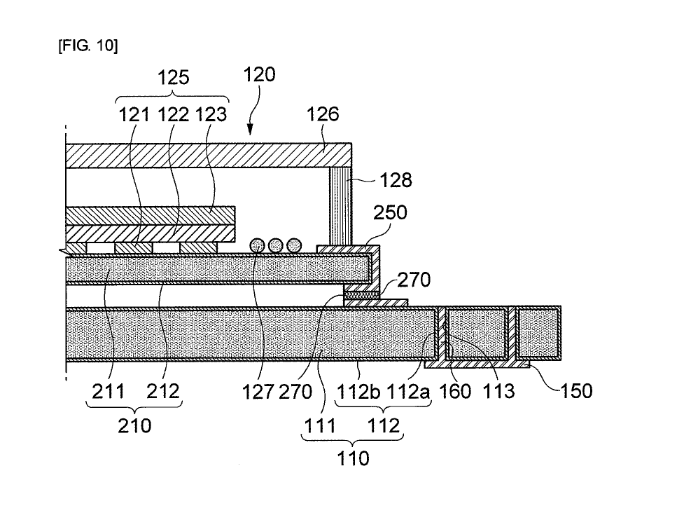

FIGS. 9 to 11 are cross-sectional views showing methods for manufacturing a light emitting module in accordance with a fifth embodiment of the present invention, respectively. In the fifth embodiment of the present invention, it is possible to manufacture a light emitting module by the same manufacture process as that of the above-mentioned fourth embodiment, except for the formation of the light emitting component unit. Thus, the same technical construction of the modification as that of the fourth embodiment will not be described, and like reference numerals will be attached to the same components of the modification as those of the fourth embodiment.

Referring to FIG. 9, a light emitting module of the fifth embodiment of the present invention may be manufactured by performing the following steps. First, a heat radiating substrate 110 with the through holes 113 is formed. Thereafter, the heat radiating substrate 110 has vias 160 formed thereon, and the circuit wiring layers 150 disposed on its top and bottom. The vias 160 are disposed at the through holes 113, and the circuit wiring layers 150 are interconnected to each other by the vias 160.

Referring to FIG. 10, the light emitting component unit 120 is formed on the heat radiating substrate 110.

Herein, in order to form the light emitting component unit 120 on the heat radiating substrate 110, the light emitting component substrate 210 is formed.

The light emitting component substrate 210 may include an additional metal substrate 211 and an additional insulating layer 212 formed along all outer surfaces of the additional metal substrate 211.

Herein, the additional metal substrate 211 may be made of a material with a high heat conductivity, for example, Al, Ag, Cu, Fe, Cr, Mg, and an alloy of at least one of these metallic materials.

The additional insulating layer 212 may play a role of giving an electrical insulation to the light emitting component substrate 210. Also, the additional insulating layer 212 may be made of an insulating material with heat conductivity. In this case, surfaces of the additional metal substrate 211 are subjected to an anodizing process to thereby form the additional insulating layer 212. That is, the additional insulating layer 212 may be made of metal oxidize constituting the additional metal substrate 211. As for another method for forming the additional insulating layer 212, a vapor deposition of heat-conductive insulating material may be used. In this case, as for the heat-conductive insulating material, any one of aluminum oxide, silicon oxide, silicon nitride, boron nitride, aluminum nitride, and so on may be exemplified. Thus, the light emitting component substrate 210 can easily emit the heat produced from the light emitting component 125 to the outside.

On the light emitting component substrate 210, the connection wirings 250 electrically connected to a light emitting component 125 to be later described may be formed. In more particular, the connection wirings 250 may be electrically connected to the first and second electrodes 121 and 123 of the light emitting component 125, respectively. Herein, the connection wirings 250 may be formed along the upper surface and side surface of the light emitting component substrate 210.

In addition to this, the connection wirings 250 may be extended toward the lower surface of the light emitting component substrate 210. As for another shape of the connection wirings 250, the both sides of light emitting component substrate 210 are provided with the connection wirings 250 by which interlayer connection can be achieved through additional vias 260.

After the light emitting component substrate 210 is formed, the first electrode 121, the organic light emitting layer 122, and the second electrode 123 are successively formed on the light emitting component substrate 210 to thereby form the light emitting component 125. Herein, although it is illustrated with the assumption in which the light emitting component 125 corresponds to an organic EL, the present invention is not limited thereto, and the light emitting component 125 may be an inorganic EL or an LED.

After the light emitting component 125 is formed on the light emitting component substrate 210, getters 127 for removal of moisture are disposed on the light emitting component substrate 210. Thereafter, on the light emitting component substrate 210, the sealing member 128 is formed along the periphery of the light emitting component 125 and the getters 127. Thereafter, the sealing substrate 126 is bonded on the light emitting component substrate 210 through the sealing member 128 so as to seal the light emitting component 125 and the getters 127, thereby forming the light emitting component unit 120.

Thereafter, after the light emitting component unit 120 is formed, the connection wirings 250 and the circuit wiring layers 150 are electrically interconnected to each other, and the light emitting component unit 120 is mounted on the heat radiating substrate 110. In this case, the connection wirings 250 and the circuit wiring layers 150 may be electrically interconnected to each other by a conductive adhesion member 270, for example, a solder or a conductive adhesive resin.

Also, through the conductive adhesion member 270, the light emitting component unit 120 and the heat radiating substrate 110 may be bonded to each other.

In addition, although not shown in the drawings, an adhesion member is further interposed between the light emitting component unit 120 and the heat radiating substrate 110, so that it is possible to more stably mount the light emitting component unit 120 on the heat radiating substrate 110. In this case, the adhesion member includes a heat conductive filler to thereby effectively transfer heat from the light emitting component unit 120 to the heat radiating substrate 110.

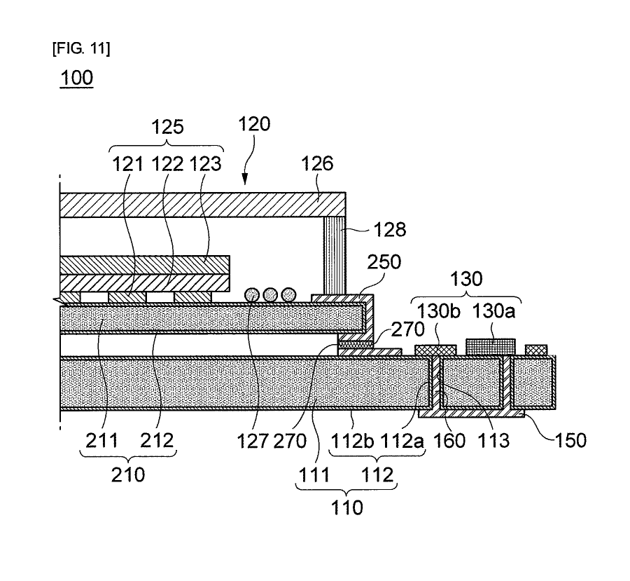

Referring to FIG. 11, after the light emitting component unit 120 is formed on the heat radiating substrate 110, the driving circuit unit 130 and the passive component 140 are mounted on the heat radiating substrate 110. Thus, the light emitting component unit 120 having a separate light emitting component substrate 210 may be mounted on the heat radiating substrate 110 having the driving circuit unit 130 mounted thereon.

Therefore, as in the embodiment of the present invention, a separate light emitting component may be formed on the light emitting component substrate with heat radiation characteristics, and then the separate light emitting component may be mounted on the heat radiating substrate, so that it is possible to maximize a heat radiation effect of the light emitting module.

A light emitting module of the present invention includes a light emitting component unit and a driving circuit unit, so that it is possible to effectively emit heat produced from the light emitting module, which makes it possible to prevent an efficiency and a lifetime of the light emitting module from being lowered due to deterioration caused by heat.

Also, in the light emitting module of the present invention, the light emitting component unit and the driving circuit unit are mounted on one heat radiating substrate, so that it is possible to reduce occurrence of noises due to a temperature difference between the light emitting component unit and the driving circuit unit.

Also, in the light emitting module of the present invention, both surfaces of the heat radiating substrate are provided with circuit wiring layers, so that it is possible to increase a degree of integration of circuit wirings and parts mounted on the heat radiating substrate, and to simplify corresponding processes.

Also, in the light emitting module of the present invention, a light emitting component is formed on a metal substrate including an insulating layer, so that it is possible to increase a heat radiation effect of the light emitting module.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A light emitting module comprising:
a heat radiating substrate which includes a metal substrate with through holes, an internal insulating layer formed along inner walls of the through holes, and an external insulating layer covering all outer surfaces of the metal substrate;
a light emitting component unit disposed on a top surface of the heat radiating substrate;
a driving circuit unit which is electrically connected to the light emitting component unit, and is mounted on the heat radiating substrate to apply a driving signal to the light emitting component unit;
a passive component which is mounted on the heat radiating substrate and is electrically connected to the driving circuit unit; and
circuit wiring layers which are disposed on a top and a bottom of the heat radiating substrate, respectively, and are interconnected therebetween through vias formed on the through holes with the internal insulating layer of the heat radiating substrate, and play a role of electrical interconnection of the driving circuit unit and the light emitting component unit, or the driving circuit unit and the passive component.

2. The light emitting module of claim 1, wherein the internal insulating layer and the external insulating layer are integrally formed.

3. The light emitting module of claim 1, wherein the internal insulating layer and the external insulating layer may be made of any one of oxide, silicon oxide, silicon nitride, boron nitride, and aluminum nitride of metallic materials constituting the metal substrate.

4. The light emitting module of claim 1, wherein the light emitting component unit may include any one of an organic EL, an inorganic EL, and an LED.

5. The light emitting module of claim 4, wherein the light emitting component unit further includes a light emitting component substrate having the light emitting component mounted thereon.

6. The light emitting module of claim 5, wherein the light emitting component substrate includes an additional metal substrate, and an additional insulating layer which covers all outer surfaces of the additional metal substrate.

7. The light emitting module of claim 5, wherein the light emitting component substrate has additional vias formed therethrough by which the light emitting component is electrically interconnected to the driving circuit unit mounted on the heat radiating substrate.

8. The light emitting module of claim 5, wherein the light emitting component substrate has connection wirings by which the light emitting component is electrically interconnected to the driving circuit unit mounted on the radiating substrate, wherein the connection wirings are disposed on the side surface along the top surface of the light emitting component substrate.

9. The light emitting module of claim 1, wherein the light emitting component unit and the heat radiating substrate are bonded on each other through an adhesion member.

10. The light emitting module of claim 9, wherein the adhesion member includes a heat conductive filler.

11. The light emitting module of claim 9, wherein the adhesion member electrically connects the connection wirings to the circuit wiring layers, and includes a solder and a conductive adhesive resin.

12. A method of manufacturing a light emitting module comprising the steps of:
forming a heat radiating substrate which includes a metal substrate with through holes, an internal insulating layer formed along inner walls of the through holes, and an external insulating layer covering all outer surfaces of the metal substrate;
forming circuit wiring layers on a top and a bottom of the heat radiating substrate to provide interlayer connection through vias formed on through holes with internal insulating layer; and
mounting a light emitting component unit, a driving circuit unit, and a passive component on a top surface of the heat radiating substrate, wherein the driving circuit unit, the driving circuit unit, and the passive component are interconnected to one another through the circuit wiring layers.

13. The method of claim 12, wherein the internal insulating layer and the external insulting layer are formed by performing anodizing treatment for surfaces of the metal substrate with the through holes, or by using vapor deposition of a heat conductive insulating material.

14. The method of claim 12, wherein the light emitting component unit includes any one of an organic EL, an inorganic EL and an LED.

15. The method of claim 14, wherein the light emitting component unit includes a light emitting component substrate having the light emitting component mounted thereon.

16. The method of claim 15, wherein the light emitting component substrate includes an additional metal substrate, and an additional insulating layer formed on all outer surfaces of the additional metal substrate, wherein the additional insulating layer is formed by anodizing treatment for surfaces of the additional metal substrate, or by using vapor deposition of a heat conductive insulating material.

17. The method of claim 15, wherein the light emitting component unit and the heat radiating substrate are bonded through an adhesion member.

18. The method of claim 17, wherein the adhesion member includes a heat conductive filler.

19. The method of claim 17, wherein the light emitting component substrate and the heat radiating substrate are electrically interconnected to each other, and the adhesion member is formed of a solder or a conductive adhesive resin.
